(19) United States
(12) Patent Application Publication
(10) Pub. No.: US 2009/0223511 A1
(43) Pub. Date: Sep. 10, 2009

(54) Unglazed photovoltaic and thermal apparatus and method

(76) Inventor: Edwin B. Cox, Chapel Hill, NC (US)

Correspondence Address: BECK AND TYSVER P.L.L.C., 2900 THOMAS AVENUE SOUTH, SUITE 100, MINNEAPOLIS, MN, 55416, US

(21) Appl. No.: 12/074,523

(22) Filed: Mar. 4, 2008

(51) Int. Cl. F24J 2/00; H01L 31/042

(52) U.S. Cl. 126/714; 136/248

(57) ABSTRACT

A photovoltaic/thermal solar panel is presented which contains no glazing above the photovoltaic array. The absence of glazing allows the photovoltaic cells to operate at a lower temperature and therefore at a higher efficiency. In addition, the absence of glazing allows the present invention PV/T panel to be used to provide nighttime cooling for a building. The panel is constructed by adhering an aluminum heat transfer plate to the rear of the PV array in the panel using a silicone adhesive. PEX tubing is inserted into channels integrally formed into the back of the heat transfer plate again using silicone or other heat-conductive compound.

### FIELD OF THE INVENTION

The present invention relates to the field of solar energy panels. More specifically, the present invention relates to an improved hybrid thermal and photovoltaic panel that can be used for nighttime thermal dissipation as well as a method for converting photovoltaic panels into a hybrid system.

### BACKGROUND OF THE INVENTION

Devices for collecting and converting solar energy are very useful because they are capable of generating energy without consuming costly fuel or creating noxious emissions. Photons in the visible range constituting the greater portion of solar energy are a high quality energy source, in that they can be readily converted into other forms of energy at useful levels of efficiency. Two well-known devices for effectively converting solar energy are photovoltaic or “PV” arrays and solar thermal collectors. Photovoltaic arrays consist of a plurality of photovoltaic cells that convert solar energy directly into electricity. Solar thermal collectors convert solar energy into thermal energy, and are primarily used for water heating or as part of a building's heating system. One of the primary advantages of both of these devices is that they can be successfully implemented in a small scale, allowing an individual homeowner to implement one or both types of solar energy conversion.

A photovoltaic array typically works at no more than about 20 percent efficiency in generating electricity, with most commercially available PV arrays operating at efficiencies between 14 and 17 percent. The majority of the solar energy incident upon a PV array goes to waste in the form of heat. This heat is radiated back into the atmosphere, removed by convection into ambient air, or conducted away by the supporting structure. Therefore, numerous attempts have been made to harvest the heat and convey it elsewhere for use rather than have it go to waste. When thermal capabilities are combined with photovoltaic capabilities, the collector units are known as hybrid PV/thermal collectors or “PV/T” collectors. These types of collectors are well known in the art but have heretofore not been able to match the performance of PV and thermal collectors separately optimized for their applications. Thus, most installations where both thermal energy and electricity are needed at a single site employ separate collectors.

Most existing PV/T systems share the characteristic that they have been designed for heat collection at relatively high temperature heat (e.g., 120-160 degrees F.). To reach this temperature, they employ an insulative glazing. Glazing in this context refers to a sheet of glass or plastic or other transparent sheet that is highly transmissive of visible light, and is non-transmissive to longwave infrared (IR). A glazing typically forms the outer, skyward facing surface of the sealed enclosure containing the PV array. A glazing that is merely protective may be in thermal contact with the PV array. However, where there is an insulative glazing, a gap is left between the PV array and the transparent sheet. This gap is preferably filled with a gas, such as one of the inert gases, but could potentially be a vacuum. The insulative glazing allows solar energy to enter the enclosure and fall upon the PV array where it is converted to either electricity or heat. At the same time the insulative glazing materially reduces the escape of the generated heat into the atmosphere. This, of course, raises the temperature inside the enclosure, which in turn improves the ability of the PV/T panel to convert the heat into usable thermal energy.

U.S. Pat. Nos. 4,392,008, 4,493,940, 4,587,376, and 6,018,123 represent various embodiments of PV/T collectors that capture thermal energy by creating a thermal path from a PV cell to a heat transfer fluid. They are remarkably similar in objective, if modestly diverse in detail. All incorporate a sealed enclosure with an insulative glazing into their design.

Two PV/T systems without insulative glazing are described in prior art. U.S. Pat. No. 6,630,622 B2 describes the use of a copper plate, a copper-filled epoxy and copper tubing to create a thermal pathway between the PV array and heat transfer fluid circulating in the tubing. The specified use of copper exacts a substantial cost in price of the material, weight added to the system and complexity of fabrication (soldering, brazing, etc). In addition, the Fresnel lens used in this system is separated from the PV array by a gap. Since this gap is not part of a sealed system, the lens is not technically an insulative glazing as outside air is allowed to flow between the lens and the PV array. Nonetheless, this transparent layer is not in thermal contact with the PV array, and therefore this layer substantially hinders the outward flow of long-wave infrared radiation from the PV array. U.S. Pat. Application Publication 2004/0025931 describes a system consisting of a fluid-filled chamber behind the PV array and in thermal contact with it by means of a steel heat exchanger. Fluid is guided by partitions through the chamber in a serpentine path from an inlet to an outlet. The fluid partitions make this type of array difficult to construct and maintain when compared to a tubing system.

There remains an unmet need in the art for a robust apparatus that can be easily assembled from inexpensive, readily available components, and that efficiently transfers thermal energy to and from a heat transfer fluid.

### SUMMARY OF THE INVENTION

The present invention discloses a combination photovoltaic and thermal solar energy panel. This PV/T panel improves upon the prior art by recognizing the need to eliminate insulative glazing from the panel. The absence of insulative glazing allows the photovoltaic cells to operate at a lower temperature and therefore at a higher efficiency. In addition, the absence of insulative glazing or any other transparent layer that is not in thermal contact with the PV array allows the present invention PV/T panel to be used to provide nighttime cooling for a building.

The absence of the insulative glazing is efficiently combined in the present invention with a unique construction process. A standard PV panel is converted into a PV/T panel by adhering an aluminum heat transfer plate to the rear of the PV array using a silicone adhesive. This heat-conductive adhesive assures effective heat transfer between the PV array and the heat transfer plate. PEX (cross-linked polyethylene) tubing is then inserted into channels integrally formed into the back of the heat transfer plate. By again using silicone or other heat-conductive compound between the PEX tubing and the heat transfer plate channels, the present invention assures low heat resistance as heat is effectively transferred from the PV array through the heat transfer plate and the PEX tubing into the heat transfer fluid running through the PEX tubing.

### BRIEF DESCRIPTION OF THE DRAWINGS

FIG. 1 is a schematic diagram of a simplified water heating application using a PV/T panel of the present invention.

FIG. 2 is a schematic diagram of a simplified space heating application using the PV/T panel of FIG. 1.

FIG. 3 is a flow chart of the process for converting a non-glazed PV panel into a non-glazed PV/T panel of the present invention.

FIG. 4 is a bottom plan view of the combined PV/T panel of the present invention with the bottom panel and insulation removed to show the heat transfer plates and tubing in place constructed according to the present invention.

FIG. 5 is an enlarged fragmentary cross-sectional view of the apparatus taken substantially on line 5 shown in FIG. 1.

FIG. 6 is a schematic diagram of energy flows using the present invention to both receive and radiate solar thermal energy.

### DETAILED DESCRIPTION OF THE INVENTION

### Recognition of the Problem

Prior art PV/T systems work by using an insulative glazing to retain heat within the panel. This heat retention allows the heat transfer fluid that removes heat from the panel to reach a higher temperature. This in turn extends the range of potential applications and allows heat to be carried away from the panel at lower fluid flow rates. However, as recognized by the applicant, the use of higher working temperatures in the PV/T panel comes at a significant cost. The differential coefficients of thermal expansion of insulative glazing and frame require intricate provisions to maintain sealing integrity under the wide temperature variations encountered. Evacuation of gas from the enclosure or instillation of an inert gas is also usually required to prevent PV deterioration. These measures add to the weight, complexity, cost and maintenance requirements of glazed PV/T systems, thus decreasing their practical application while also compromising the electric conversion efficiency. Finally, the presence of an insulative glazing eliminates the opportunity to efficiently radiate heat outward from the PV array for cooling purposes, since glazing is non-transmissive to longwave IR.

An additional benefit to eliminating the insulative glazing from PV/T panels is that the temperature of the panel during electrical generation is reduced. This reduced temperature materially increases the efficiency of the photovoltaic cells that are converting sunlight into electricity. Prior art PV/T panels use insulative glazing to increase the efficiency of the thermal collection, but this improved efficiency comes at the cost of reducing the efficiency of the photovoltaic cells.

### Overview of the System

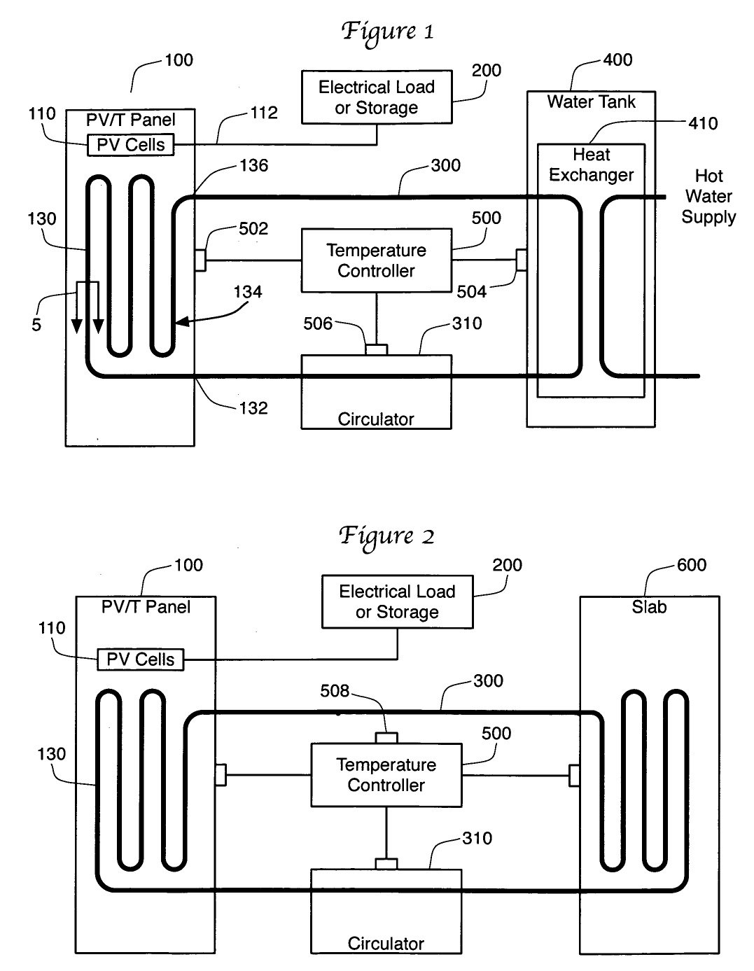

FIG. 1 show a schematic view of a residential system using the PV/T panel or collector 100 of the present invention for electrical generation and water heating. FIG. 1 does not show several elements that would be required for practical implementation of the present invention, such as the valves that switch among the various modes of operation or the backup boiler that provides heat on cloudy days. These elements are well known in the art, and are not directly relevant to the inventive aspect of the present invention. The PV/T panel 100 receives solar energy from the sun (not shown). Photovoltaic cells 110 which form part of the photovoltaic array 140 (not shown in FIG. 1) convert light energy into electricity, which is then extracted from the panel 100 through wires 112. The wires are preferably attached to an electric junction secured within the panel 100. The electricity can be used immediately at the location of the panel 100, stored in an electric storage system, or sent into an electrical power grid. These options are jointly represented in FIG. 1 as electrical load or storage 200.

In addition to the generation of electricity, the PV/T panel 100 is capable of generating useful heat energy. As explained in further detail below, this is accomplished by passing a heat transfer fluid through a fluid system that transfers heat energy in the panel to the transfer fluid. This transfer fluid is preferably of a chemical composition that will not freeze within the expected temperature range of the environment of the panel 100. The anti-freeze heat transfer fluid in the system of FIG. 1 passes through the transfer fluid tube system 300. The transfer fluid tube system 300 includes an internal heat exchange system or heat collector portion 130 within the PV/T panel 100, which is described in more detail below. Cool transfer fluid enters this system 130 at input 132, receives heat from the panel 100 in serpentine section 134, and exits the panel heated at exit 136. In the preferred embodiment, the input 132 and output 136 are fitted with appropriate plumbing fixtures to allow secure attachment of tubing or piping to the heat exchange system 130 of the panel 100.

Although section 134 is shown as a serpentine in shape in FIG. 1, other configurations of the heat collector portion 130 within the PV/T panel 100 are also possible. For example, it would be possible to lay multiple sections of tubing in parallel, with each of these sections connected to a source tube on one end and a discharge tube on the other end. Heat transfer fluid would then enter the heat collector portion 130 at input 132, flow from the input tube simultaneously through the parallel tubing sections, and be collected at the output tube to leave the panel 100 through output 136.

A pump that forms part of the circulator 310 effects the movement of fluid through system 300. Heat transfer fluid passes in a closed loop from the circulator 310, through the internal heat exchange system 130 in the panel 100, on to an internal heat exchanger 410 within a water tank 400, and back to the circulator 310. The circulator 310 operates when the temperature of the panel 100 exceeds the temperature of the water in the hot water tank 400. The temperature of the heat transfer fluid rises as it passes through the panel 100 and falls as it gives up its heat to the tank 400. A differential temperature controller 500 uses signals from temperature probes in the panel 502 and the tank 504 to determine when to send a signal to the circulator controller 506 informing the circulator 310 when to start and stop the pump. If the hot water in the tank reaches a maximum desired temperature but the panel is still yielding heat, the heat transfer fluid is diverted to a heat disposal mechanism, such as an outdoor fountain.

FIG. 2 is similar to FIG. 1, except that it shows a residential system that uses the present invention for electric generation and space heating and cooling. In this Figure, the PV cells 110 provide electricity to the electrical load or storage 200 just as in FIG. 1. The difference from FIG. 1 is that the heating capabilities of the panel 100 are being used to heat a concrete slab 600 or other thermal mass within a dwelling or other building. The circulator 310 operates to bring heat to the slab 600 whenever the temperature controller 500 indicates that the temperature of the panel 100 exceeds the effective temperature of the slab 600. Heat transfer fluid passes in a closed loop from the circulator 310 through the tubing in the collector 130, on through the tubing loops in the slab 600, and back to the circulator 310. The temperature of the heat transfer fluid rises as it passes through the heat collector 130 and falls as it gives up its heat to the slab 600. As described above, the temperature controller 500 uses signals from temperature probes in the slab 600 and the collector 130 to determine when to start and stop the motor in circulator 310. In addition, a thermostat 508 on the temperature controller 500 can be located in the dwelling unit to control the amount of heat that is provided to the slab 600. Although not shown in FIG. 2, many heating systems using this type of a layout will use a heat exchanger to separate the heat transfer fluid passing through the present invention PV/T panel 100 from ordinary water that is used to actually heat the slab 600.

One of the primary benefits of the present invention is that, in addition to winter-time heating, the present invention panel 100 is ideally designed to allow for night sky radiant cooling in the summer. When used in this capacity, the circulator 310 operates when the temperature of the panel 100 falls below the effective temperature of the concrete slab 600. Heat transfer fluid passes in a closed loop from the circulator 310 through the tubing in the collector 130, on through the tubing path within the slab 600, and back to the circulator 310. The temperature of the heat transfer fluid falls as it passes through the collector and rises as it accepts heat from the slab. The thermostat 508 provides overall control over the circulation system 300 and the controller 310 to ensure that the dwelling is maintained at a comfortable temperature.

### Construction

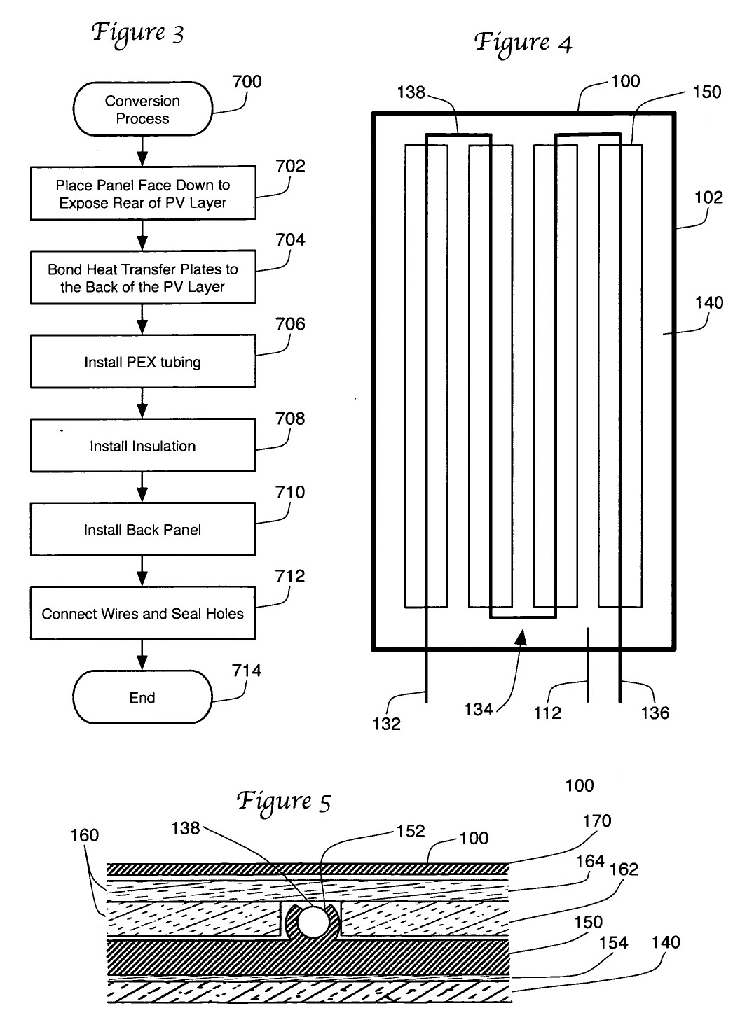

Another benefit of the present invention is that it can be implemented through a simple conversion process where a standard PV panel is converted into PV/T panel 100. This process 700 is set forth in the flow chart of FIG. 3, which can be read in conjunction with the rear plan view of panel 100 in FIG. 4 and the fragmentary cross-sectional view of FIG. 5. FIG. 4 shows the panel 100 with the rear panel 170 and insulation 160 removed. FIG. 5 is a cross sectional view of the panel 100 showing all of the layers of the panel 100 including the tubing 138. One potential location for this cross-sectional view is along line 5 as indicated in the schematic diagram of FIG. 1.

A suitable PV panel for conversion is the Uni-Solar ES-62T framed solar module manufactured by United Solar Ovonic LLC, Auburn Hills, Mich. This PV module is 49.5 inches long by 31.2 inches wide and contains a photovoltaic layer or array 140 that is responsible for converting solar to electrical power.

The ES-62T panel has a rectangular black-anodized aluminum frame 102 that is 1.25 inches deep and open on the back side. Securely attached horizontally within the frame 102 on its front side is the PV array 140. This array 140 forms the top cover of the panel 100, with the light-accepting surface of the array 140 facing outward. The PV array 140 in the ES-62T PV panel consists of PV cells encapsulated in ETFE high-light-transmissive polymer (sold by Dupont under the trademark Tefzel®) that are in turn mounted on an 0.024 inch aluminum-zinc alloy coated steel (sold by BIEC International Inc. under the trademark Galvalume®) sheet backing. This transparent ETFE glazing is a protective glazing but does not constitute an insulative glazing because it is not separated from the PV array 140 by an air or vacuum gap. In consequence, heat is efficiently transmitted from the PV cells to the surface of the glazing, from where it is released by radiation or convection. Conversely, IR or convective heat incident upon the ETFE glazing is readily transmitted to the PV cells.

The first step 702 in the process 700 of converting a standard PV panel into the PV/T panel 100 of the present invention is to place the PV panel face down. This exposes the back surface of the PV layer 140, which, in the context of the Uni-Solar ES-62T, consists of the Galvalume sheet. The next step 704 is to mount heat transfer plates 150 directly to the back of the PV layer 140. In FIG. 4, four heat transfer plates 150 are shown. However, in the preferred embodiment, eight aluminum heat transfer plates 150 are used, with each plate 150 being 48 inches long and 3.5 inches wide. These transfer plates 150 are constructed with channels 152 running their entire lengths, with the channels 152 being specially constructed in order to fit ½ inch I.D. PEX (cross-linked polyethylene) tubing. This type of heat transfer plate is available commercially, with the preferred embodiment using Wirsbo-Uponor Joist-Trak® heat transfer plates. An approximately 0.002 inch layer of silicone adhesive 154 (e.g., GE Silicone II Clear®) is spread between the plates 150 and the PV layer 140 to bond the two components. The plates 150 are held in place on the Galvalume sheet 140 with clamping or weights until the bond matures. Small portions of heat transfer plate may need to be cut out to clear electrical connection terminals or allow bends in the tubing.

At step 706, sections of ½ inch I.D. PEX tubing 138 (such as the commercially available Zurn PEX tubing) are cut to length to fit in heat transfer plate channels 152. Tubing ends are connected with short lengths of PEX tubing and right angle connectors, to form a serpentine path 134. The unconnected ends of each outermost tubing section exit the frame through holes drilled in the frame to the appropriate diameter and caulked with silicone. Alternatively tubing ends may exit the back panel 170. The assembly of tubes is then snapped into the channels of the heat transfer plates after wetting them with a thin layer of silicone or other heat-conductive compound. Although PEX is the material of choice of tubing in the preferred embodiment, it would be possible to use other plastic tubing, especially as new and improved plastics appear in the marketplace.

The next step 708 is to install insulation 160 behind and between the PEX tubing 138. In the preferred embodiment, half-inch thick polyisocyanurate insulation 162 is cut to size to fit between the channels 152 of adjacent heat transfer plates 150 and press-fit into place. A large sheet 164 of the same insulation is then placed over the previous layer of insulation 162, tubing 138, and channels 152. The large sheet of insulation 164 is preferably flush with the edge of the frame 102. An alternative method is to use spray-on polyurethane foam insulation (Froth-Pak from Dow Chemical) instead of the polyisocyanurate panels.

At step 710, the back sheet metal panel 170 is placed over the frame and insulation. When installing this panel 170 to the back of the PV/T panel 100, it is preferred that a weatherproofing gasket or seal is placed in place between the panel 170 and the frame 102 of the PV/T panel 100. The panel 170 is preferably attached with a removable attachment mechanism such as screws or their equivalent. Alternatively, the aluminum foil covering of the large polyisocyanurate sheet can serve as the back panel 170, and to employ a suitable caulking such as polyurethane foam (Great Stuff from Dow Chemical) or silicone (Silicone II from GE) for weatherproofing. When spray-on polyurethane foam is used for insulation, no back cover is required, since its closed-cell characteristic provides weatherproofing and rigidity.

Finally, at step 712, it is necessary to ensure that the wires 112 that carry the electric current from the PV cells 110 in the PV layer 140 are routed out of the enclosure through holes in the back panel 170. These holes are then protected with a grommet and sealed with silicone. When spray-in polyurethane is employed, the wires simply exit the polyurethane and may be anchored on the polyurethane surface with small plastic pads.

### Thermal Radiant Cooling and Relevant Energy Fluxes

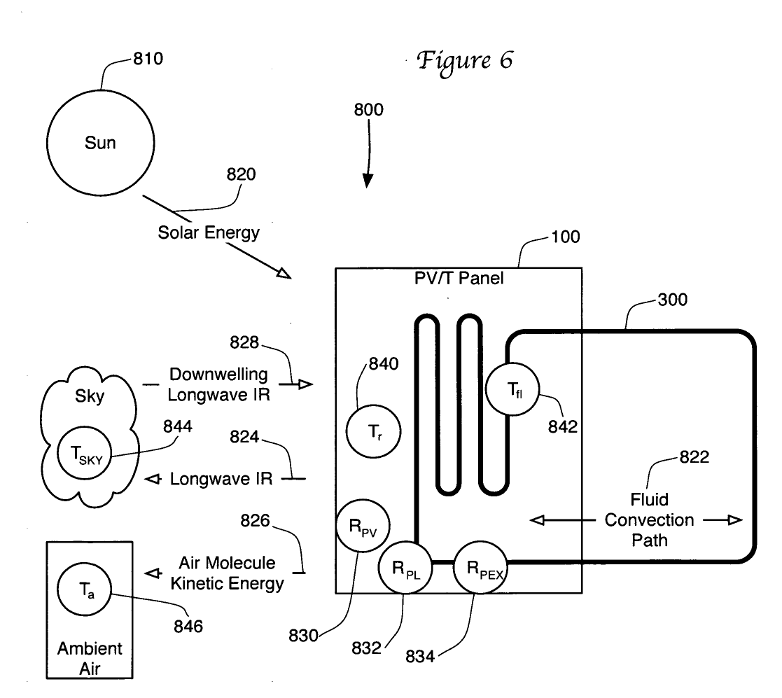

One of the primary distinctions of the present invention PV/T panel 100 is its ability to be used to not only allow thermal heating but also thermal cooling of dwelling spaces. To understand the operation of the PV/T panel 100 while cooling, it is useful to understand the relevant energy fluxes. The term flux refers to the amount of thermal or electromagnetic energy that flows through a unit area per unit time, and is represented by a vector. The energy fluxes involving the PV array 100 are depicted in the schematic flux representation 800 in FIG. 6.

Energy from the sun 810 is represented by solar energy flux 820, which consists of UV, visible light and shortwave infrared radiation. When the sun 810 is shining, the solar energy 820 is absorbed by the PV array 140, where it is transformed into thermal energy, which is to say kinetic energy of vibration of the molecules in the panel 100. Some thermal energy goes along the fluid convection path 822 in the heat transfer fluid found in the heat transfer fluid system 300, where it is put to use by heating water or heating a dwelling. The remainder of the solar energy 820 is lost from the surface of the PV array 140 as longwave infrared (IR) radiation 824 or by convection as increased kinetic energy of nearby air molecules 826. Flux 828 is downwelling longwave IR radiation from the atmosphere, as will be subsequently explained.

In order to heat the thermal fluid required for the fluid convection path flux 822, three thermal resistances 830-834 in series must be overcome. The first resistance R_{PV} 830 is the resistance of the photovoltaic array 140. The aluminum heat transfer plate is the second resistance, R_{PL} 832. The wall of the PEX tubing is the final resistance, R_{PEX} 834. Contact resistances due to microgaps between the tubing 138 and heat transfer plate channel 152 and between the heat transfer plate 150 and the PV array 140 are minimized by a very thin layer of silicone 154 used as an adhesive and heat transfer medium. Thermal resistance due to stagnant layers within the fluid itself is avoided by establishing a turbulent flow regime, achieved by sufficient fluid velocity to exceed the critical Reynolds number of ˜4000.

Conduction to the heat transfer fluid is expressed as

Q_{cond}=U_{cond}(Tᵣ−T_{fl}),

where Tᵣ 840 is the temperature of the PV array 140, and T_{fl} 842 is the fluid temperature. T_{fl} 842 is not constant but varies from Tᵢ at the inlet to Tₒ at the outlet. For practical purposes,

$${T}_{fl} = \frac{{T}_{i} + {T}_{o}}{2} ,$$

the average of Tᵢ and Tₒ. U_{cond} is the reciprocal of the sum of series resistances,

$${U}_{cond} = \frac{1}{( {R}_{PV} + {R}_{PL} + {R}_{PEX} )} .$$

Convection is expressed by the equation

Q_{conv}=U_{conv}(Tᵣ−Tₐ),

where

U_{Conv}=A_{c}+B·V_{z},

with V_{z} being wind velocity at the panel. Parameter A_{c} represents natural convection, that is, the component occurring in the absence of wind, while B reflects the forced convection component due to the wind. When air temperature 846 is below PV array temperature 840, as is usual, convection cools the array. If the air temperature 846 is higher than the PV array temperature 840, convection heats the PV array 140.

Radiant energy leaving the PV array (flux 824) is expressed as

Q_{rad+}=σεᵣTᵣ⁴,

where σ is the Stefan-Boltzmann constant, εᵣ is the surface emissivity and Tᵣ 840 is absolute temperature of the array. A range of wavelengths is emitted as described by Planck's law with a peak temperature given by the Wein displacement law. At typical ambient temperatures, for example 70° F., terrestrial objects with high emissivity emit approximately 135 Btu per hour per ft² concentrated in the far infrared (IR) spectrum with a peak wavelength of around 10 microns.

When exposed to the open sky, the IR energy 824 emitted by the PV array 140 travels upward through the atmosphere, where it meets a variety of fates depending on its wavelength. The atmosphere is transparent to certain wavelengths, which pass through the atmosphere into space unattenuated. Other wavelengths are absorbed by molecules in the atmosphere, including especially CO₂ and H₂O. The absorbed energy is eventually reradiated, some outward and ultimately into space.

The energy reradiated earthward from the atmosphere and absorbed by the PV array (flux 828) is expressed as

Q_{rad-}=σεᵣTₐ⁴,

T_{sky} 844 is a calculated equivalent sky temperature, defined by

T_{sky}⁴=ε_{sky}Tₐ⁴,

where Tₐ 846 is the absolute outdoor air temperature and ε_{sky} is an empirically determined emissivity factor found to depend strongly on atmospheric water content. A number of correlations for clear night sky emissivity have been reported, for example, one by Chen et al (1995) based on dew point temperature in degrees Celsius, T_{dp},

ε_{sky,clear}=0.736+0.00577*T_{dp}.

The presence of clouds is addressed with the cloudiness factor of Clark and Blanplied (1979), Cₐ, where n is cloud cover expressed as a fraction from 0 (clear) to 1.0 (overcast),

Cₐ=1.000+0.0224*n+0.0035*n²+0.00028*n³,

leading to the final formulation

ε_{sky}=ε_{sky,clear}Cₐ.

Energy lost as infrared radiation and convection from the underside of the panel must be considered. In practical use, sufficient insulation is applied to the bottom so that its exchange with its environment is small compared to that between the top and the atmosphere, so losses from the back may be ignored.

The energy balance on the PV array is given by

Qₙₑₜ=Qₛᵤₙ−σεᵣ(Tᵣ⁴−T_{sky}⁴)−U_{conv}(Tᵣ−Tₐ)−U_{cond}(Tᵣ−T_{fl}).

When Qₙₑₜ=0, the system is at equilibrium. When Qₙₑₜ is positive, Tᵣ rises, and when Qₙₑₜ is negative, Tᵣ falls, until equilibrium is reached. During disequilibrium, in addition to changing fluxes defined in the equation, heat is also stored in the thermal mass of the PV array as Tᵣ rises or is withdrawn from it as Tᵣ falls,

ΔQ_{PV}=m_{PV}cₚΔTᵣ,

where m_{PV} is the mass of the array and cₚ is its specific heat capacity.

### Lack of Glazing

As described above, a glazing layer is a layer that exists above the PV array 140 that is effectively transparent to visible light and which blocks a significant portion of infrared radiation. This transparency need not be complete, but it should not significantly block the amount of useable light that is received by the PV array to be converted into electricity. Since the useful wavelengths for generating electricity in a PV array 140 are confined to the visible spectrum, useful glazings are at least eighty-five percent transmissive of visible light. Glazings that are less transparent would negatively affect the efficiency of the array. Consequently, for the purposes of this invention, a glazing is transparent if it allows eighty-five percent of visible light to pass through. All known transparent glazings that are sufficiently rigid for the structure of the PV panel 100 will block a significant portion of infrared radiation emanating from the PV array 140.

The PV panel 100 of the present invention is purposefully designed without a glazing layer between the PV array 140 and the sun 810. If a glazing layer were present, especially an insulative glazing with a sealed enclosure, the energy flux situation would be dramatically altered. The quantitative description with an insulative glazing present is considerably more complex but need not be considered here. Qualitatively, the glazing passes solar energy 820 but blocks and absorbs outgoing longwave IR 824 emitted from the PV array 140 and prevents convection 826 from directly interacting with the PV array 140. The temperature of the PV array 140 rises until the temperature of the insulative glazing is high enough to give off as much by IR radiation and convection as is being received from the sun, less the amount 822 transferred to the heat transfer fluid.

These effects of an insulative glazing and sealed enclosure can be very beneficial in a purely thermal solar collector. However, in combined PV/T collector such as panel 100, the higher temperature of the PV array 140 decreases the efficiency of electricity generation. Another undesired effect of the insulative glazing is that, at night, longwave IR radiation 824 from the array would be blocked and absorbed by the glazing. In addition, the heat loss through convection 826 is drastically altered.

Heating and Cooling without Glazing

During heating applications, significant amounts of thermal energy will flow to the heat transfer fluid only if the conductance along that pathway 830-834 is high relative to losses by radiation and convection. Meticulous attention has been paid to maximizing the conductance of the path to the heat transfer fluid (i.e., reducing resistances 830-834) in order that sufficient thermal energy is collected to justify the expense and effort of doing so. Highlighting that necessity is a key aspect of this invention.

Thermal analysis of the circuit indicated that a total series resistance R_{cond} of approximately 0.15 would be achievable, equivalent to a conductance U_{cond} of 7 Btu/ft²-° F. This value is compatible with reasonable efficiency for both heating and cooling applications. Prototypes have achieved values in this range.

The potential for space cooling achieved by radiating heat to the night sky has long been recognized. Cooling is accomplished by converting thermal energy into IR energy 824, which is radiated away from the PV array. In operation, heat is brought to the PV/T module in the heat transfer fluid in system 300 from the space to be cooled. The heat then passes through the conductance pathway previously described to the PV array 140.

Although there is downwelling IR 828 from the atmosphere absorbed by the PV array 140, on balance, under most circumstances, more IR is radiated away 824 from the array than is received by it in return 828 from the atmosphere. Thus, the atmosphere can serve as a heat sink for night cooling using the PV/T panel 100.

A number of regimes using night sky cooling to cool interior spaces have been designed and tested. Early work used the surface of roof-mounted ponds as the heat emitter. These methods often required elaborate systems to open shutters at night and close them during the day, limiting their practicality. Parker (2005) described a concept called Night Cool in which the metal roof of a house serves as a nocturnal thermal radiator. Air from the living space is circulated into the attic at night to thermally couple the roof to the living space by convection. Computer simulation suggested that quantitatively significant cooling could be obtained in this manner. A representative calculated cooling rate is 25 Btu/ft²-hr (75 W/m²) for approximately 10 hours per night in the Southeastern U.S. A comparable analysis performed for the present invention PV/T panel 100 reveals that, under most nighttime conditions, the associated T_{sky} 844 is sufficiently below the target minimum indoor temperature to yield quantitatively useful cooling, assuming 1) there is sufficiently high thermal conductance between the PV/T panel 100 and the indoor environment and 2) the area of the panel 100 is sufficient. These requirements can be met in practice.

In operation, heat is supplied to the array from the conditioned space through the heat transfer fluid system 300, and an equilibrium temperature Tₑ is reached at which heat gain to the array 140 is just equal to heat loss to the atmosphere by radiation 824 and convection 826. If Tᵢ is the inlet fluid temperature, Tₒ is the outlet fluid temperature, Tₑ is the equilibrium array temperature, cₚ is specific heat capacity of the fluid, Aᵣ is the total array area and qₛ is fluid mass flow rate, then the heat balance equation is

(Tᵢ−Tₒ)qₛcₚ=σεᵣ(Tₑ⁴−T_{sky}⁴)Aᵣ+U_{conv}(Tₑ−Tₐ)Aᵣ.

The possibility of condensation on the PV array 140 points to a potential problem. The temperature of the panel 840 free in still air would be expected to drop below ambient air temperature 846 and could approach T_{sky} 844, limited only by convection 826. Once Tᵣ 840 falls to T_{dp}, the dew point temperature, condensation begins, and cooling by radiation 824 is then matched by heat gain from condensation of water on the surface of the array, at which point there is no further drop in Tᵣ 840. For efficient operation, the equilibrium temperature Tₑ must remain at or above T_{dp}, because otherwise the condensation could divert much of the cooling capacity. Under practical operating conditions, Tₑ is almost always above T_{dp}, and thus condensation is not a practical concern.

The most efficient use of night cooling occurs when there is sufficient thermal mass to carry the cooling effect over into the daytime. One very practical thermal mass is a concrete slab foundation 600 (shown in FIG. 2) into which tubing has been installed for radiant heating. The slab 600 gets cooled simply by reversing the direction of heat flow, so that the slab 600 supplies heat that is carried via the heat transfer fluid to the PV/T panel 100 to be emitted 824 to the sky. As the slab 600 cools below the temperature of the interior thermal masses such as the gypsum board and framing, they give up heat to the slab by radiation, and that heat is also transferred through fluid convention path 822 to the panel 100. The temperature of the slab 600 and internal thermal masses thus lowered, they are capable of absorbing heat gain into the building for many hours of the following day, delaying—or on many days avoiding—the need for vapor compression cooling.

If there is insufficient thermal mass in the slab 600 to bank the cooling capacity, then its use is limited to cooling the indoor air in lieu of vapor compression cooling for the period during which T_{sky} 824 is below the indoor temperature. If it is acceptable to set the thermostat below normal during the night, then that strategy may allow a modest degree of thermal storage in the house infrastructure—gypsum board, framing, etc.—in excess of the direct cooling.

The many features and advantages of the invention are apparent from the above description. Numerous modifications and variations will readily occur to those skilled in the art. Since such modifications are possible, the invention is not to be limited to the exact construction and operation illustrated and described. Rather, the present invention should be limited only by the following claims.

What is claimed is:

1. A photovoltaic and thermal solar panel assembly, comprising:
a) a frame;
b) a photovoltaic array within the frame having
i) an upper surface facing skyward,
ii) a lower surface away downward,
iii) at least one photovoltaic cell on the upper surface for converting solar energy directly into electricity, and
iv) a backing sheet on the lower surface,
wherein the upper surface is exposed to the sky without the presence of a glazing layer, the glazing layer being a transparent sheet separated from the upper surface of the photovoltaic array by a gas or a vacuum;
c) at least one heat transfer plate having
i) a flat top surface bonded to the lower surface of the photovoltaic array,
ii) a bottom surface, and
iii) an integral channel formed on the bottom surface;
d) plastic tubing located within the channels of the heat transfer plates; and
e) heat transfer fluid within the plastic tubing
wherein the panel converts incoming radiant energy into thermal energy for heating during the day and the absence of the glazing layer allows for release of radiant energy to the night sky for cooling.

2. The panel of claim 1, wherein the plastic tubing is cross-linked polyethylene (PEX).

3. The panel of claim 2, wherein the tubing contacts the channel around a majority of its circumference to facilitate efficient heat transfer, and further wherein the tubing is interconnected in a manner for incoming fluid to be distributed and recollected over a large portion of the area of the panel.

4. The solar panel of claim 2, further comprising:
f) a bottom cover plate that is secured to the frame.

5. The solar panel of claim 4, further comprising:
g) one layer of foam insulation between the heat transfer plate channels and a second layer of foam insulation between the first insulation layer and the bottom cover plate.

6. The solar panel of claim 2, further comprising:
f) a layer of spray-on polyurethane foam insulation applied to the plastic tubing and the bottom surface of the heat transfer plate.

7. The solar panel of claim 2, further comprising:
f) a temperature sensor for measuring a temperature of the panel;
g) an electrical junction for electric connection to the photovoltaic cells; and
h) plumbing fixtures attached to the PEX tubing for plumbing connection to both ends of the PEX tubing.

8. The solar panel of claim 2, wherein the PEX tubing is impressed into the heat transfer plates with an intervening layer of heat-conductive compound.

9. The solar panel of claim 1, wherein the heat transfer plates and integral channel are formed of aluminum.

10. The solar panel of claim 9, wherein the heat transfer plates are bonded to the photovoltaic array using a heat-conductive adhesive.

11. A method of heating and cooling the interior of a building comprising:
a) mounting a combined photovoltaic and thermal solar panel exterior to the building with exposure to the open sky, the panel having:
i) a photovoltaic array for converting solar energy into electricity, wherein the photovoltaic array is exposed to the elements without the presence of a glazing layer having transparent sheet separated from the photovoltaic array by a gas or a vacuum;
ii) at least one aluminum heat transfer plate having a flat top surface bonded to a lower surface of the photovoltaic array and an integral channel formed on a bottom surface;
iii) plastic tubing located within the channels of the at least one heat transfer plate and interconnected in a manner for incoming fluid to be distributed and recollected over a large portion of the area of the lower surface of the photovoltaic array;
b) creating a closed fluid loop including the tubing located in the channels of the heat transfer plate;
c) thermally connecting the closed fluid loop to tubing passing through a building slab;
d) managing the pumping of heating fluid through the closed fluid loop using temperature sensors in the slab and the solar panel;
e) during cooling operations of the building where the sky temperature is below the current building temperature,
i) flowing a cool slab liquid through the tubing passing through the building slab so as to absorb heat, thereby cooling the interior and warming the slab fluid;
ii) conveying a warm panel fluid to solar panel,
iii) cooling the warm panel fluid by using the heat in the panel fluid to heat the plastic tubing, heat transfer plate, and photovoltaic array in the solar panel; and
iv) cooling the photovoltaic panel surface by radiating infrared energy upward to the cooler atmosphere and outer space; and
f) during heating operations when solar radiant energy is being received by the solar pane,
i) flowing a warm slab liquid through the building slab so as to release heat, thereby warming the interior and cooling the fluid;
ii) conveying a cool panel fluid to the solar panel;
iii) warming the cool panel fluid by using visible and infrared energy of sunlight to heat the photovoltaic array in the solar panel, which heat is conducted through the panel, through the heat transfer plate and plastic tubing to the cold fluid.

12. The method of claim 11, wherein the closed fluid loop includes the tubing passing through the building slab, and further wherein the panel fluid and the slab fluid are the same fluid.

13. The method of claim 11, wherein the closed fluid loop is thermally connected to the tubing passing through the slab through a heat exchanger, and further wherein the panel fluid and the slab fluid remain isolated from each other.

14. The method of claim 11, wherein the panel fluid is a heat transfer fluid with anti-freeze properties, and the slab fluid is water.

15. The method of claim 11, further comprising, during heating operations, cooling the photovoltaic array during the process of warming the cool panel fluid, thereby increasing the efficiency of the electrical conversion in the photovoltaic array.
